(19) United States
(12) Patent Application Publication
(10) Pub. No.: US 2025/0089298 A1
(43) Pub. Date: Mar. 13, 2025

(54) THIN FILM TRANSISTOR AND DISPLAY APPARATUS COMPRISING THE SAME

(71) Applicant: LG Display Co., Ltd., Seoul (KR)

(72) Inventors: JaeHyun KIM, Paju-si (KR); JaeYoung OH, Paju-si (KR); KwangHeum LEE, Paju-si (KR); Ahrum SOHN, Paju-si (KR); Minho LEE, Paju-si (KR)

(73) Assignee: LG Display Co., Ltd., Seoul (KR)

(21) Appl. No.: 18/800,908

(22) Filed: Aug. 12, 2024

(30) Foreign Application Priority Data
Sep. 7, 2023 (KR) 10-2023-0118794

(51) Int. Cl. H01L 29/417; H01L 27/12; H01L 29/786

(52) U.S. Cl. CPC H10D 30/6729; H10D 64/258; H10D 86/423; H10D 86/60; H10D 30/6755

(57) ABSTRACT

A thin film transistor for a display device can include an active layer disposed on a substrate, a gate electrode overlapping with the active layer, a source electrode electrically connected to the active layer, a drain electrode electrically connected to the active layer, and at least one hole in the active layer, in which the at least one hole at least partially overlaps with an edge of the gate electrode. Also, the at least one hole in the active layer can control or block diffusion of a dopant within the active layer.

### CROSS-REFERENCE TO RELATED APPLICATIONS

This application claims priority to Korean Patent Application No. 10-2023-0118794 filed in the Republic of Korea, on Sep. 7, 2023, the entirety of which is hereby incorporated by reference into the present application as if fully set forth herein.

### BACKGROUND

### Field of the Invention

The present invention relates to a thin film transistor and a display apparatus including the same.

### Discussion of the Related Art

Transistors are widely used as switching devices or driving devices in the field of electronic devices. In particular, since a thin film transistor can be manufactured on a glass substrate or a plastic substrate, it is widely used as a switching device of a display apparatus, such as a liquid crystal display apparatus or an organic light emitting display apparatus.

Based on the material constituting the active layer, thin film transistors can be divided into amorphous silicon thin film transistors using amorphous silicon as the active layer, polycrystalline silicon thin film transistors using polycrystalline silicon as the active layer, and oxide semiconductor thin film transistors using oxide semiconductors as the active layer.

The amorphous silicon thin film transistor (a-Si TFT) has the advantage of short manufacturing process time and low production cost because amorphous silicon can be deposited in a short time to form an active layer, but has the disadvantage of being limited in use in active matrix organic light emitting devices (AMOLEDs) because of low mobility and poor current driving ability and a change in threshold voltage.

A polycrystalline silicon thin film transistor (poly-Si TFT) is made by crystallizing amorphous silicon after amorphous silicon is deposited. Since a process of crystallizing amorphous silicon is required in the manufacturing process of a polycrystalline silicon thin film transistor, the manufacturing cost increases as the number of processes increases, and since the crystallization process is performed at a high process temperature, it is difficult to apply the polycrystalline silicon thin film transistor to a large area device. In addition, due to its polycrystalline properties, it is difficult to secure the uniformity of the polycrystalline silicon thin film transistor.

In an oxide semiconductor thin film transistor (TFT), since the oxide constituting the active layer can be formed at a relatively low temperature, has high mobility, and has a large resistance change according to the oxygen content, desired physical properties can be easily obtained. Also, due to the nature of the oxide, since the oxide semiconductor is transparent, it is also advantageous for implementing a transparent display.

In oxide semiconductors, as the width of the active layer changes, conductorization diffusion occurs differently due to differences in oxygen compensation abilities of surrounding layers. As a result, there can be difficulty in optimizing the threshold voltage (Vth) of the thin film transistor within the same process.

Additionally, in oxide semiconductors, when the width of the active layer increases, the conductorization penetration depth increases and the length of the effective channel decreases, which can reduce the driving stability of the thin film device. In other words, when the active layer is made wide, it can be hard to control the diffusion of the dopant and conductorization may extend too deep or even under the gate electrode, which can decrease the channel area and impair driving stability. Therefore, technologies for controlling the conductorization penetration depth are continuously being researched.

A need exists of a thin film transistor that has a configuration that can provide a wide active layer while also controlling conductorization diffusion, and can provide excellent mobility and improved driving stability.

### SUMMARY OF THE DISCLOSURE

An embodiment of the present invention is to provide a thin film transistor in which the diffusion of conductorization is controlled or prevented even when the width of a channel region is increased, by including one or more holes in the active layer.

An embodiment of the present invention seeks to provide a thin film transistor in which conductorization diffusion is controlled or prevented and excellent mobility is secured by configuring holes in the active layer.

An embodiment of the present invention seeks to provide a thin film transistor with improved reliability, including an active hole, e.g., a hole in the active layer.

Another embodiment of the present invention seeks to provide a display apparatus including such a thin film transistor.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a thin film transistor that includes an active layer, and a gate electrode spaced apart from the active layer and at least partially overlapping the active layer, in which the active layer includes a channel area at least partially overlapping the gate electrode in a plan view, a source area connected to one side of the channel area in a plan view, and a drain area connected to the other side of the channel area in a plan view, an active hole in which the active layer is not disposed is disposed in a region whose edge is defined by the active layer, and the active hole includes a first active hole, at least a portion of the first active hole overlaps the gate electrode, and the first active hole includes a first area overlapping the gate electrode, and a second area that does not overlap the gate electrode, and an area of the second area is greater than or equal to an area of the first area.

When a direction parallel to a shortest line connecting the source area and the drain area is a first direction, and a direction perpendicular to the first direction is a second direction, a length of an area in which an arbitrary straight line parallel to the second direction and the first area overlap in a plane can decrease as the distance from the second area with respect to the first direction increases.

When a direction parallel to a shortest line connecting the source area and the drain area is a first direction, and a direction perpendicular to the first direction is a second direction, the first active hole includes a first source active hole disposed from the gate electrode toward the source area along the first direction in a plane, and a first drain active hole disposed from the gate electrode toward the drain area along the first direction in a plane, and the first source active hole and the first drain active hole can be spaced apart from each other.

A straight line passing through at least a portion of the first source active hole among any straight lines parallel to the first direction can pass through the first drain active hole.

A straight line passing through at least a portion of the first source active hole among any straight lines parallel to the first direction may not pass through the first drain active hole.

The first source active hole can include a first sub-active hole and a second sub-active hole spaced apart from each other, and the first drain active hole can include a first sub-active hole and a second sub-active hole spaced apart from each other.

Among any straight lines parallel to the first direction, a straight line passing through the first sub-active hole of the first source active hole can pass through the first sub-active hole of the first drain active hole, and among any straight lines parallel to the first direction, a straight line passing through the second sub-active hole of the first source active hole can pass through the second sub-active hole of the first drain active hole.

A straight line passing through at least a portion of the first source active hole among any straight lines parallel to the first direction may not pass through the first drain active hole.

The first source active hole and the first drain active hole can further include protrusion portion disposed in a direction not parallel to the first direction.

The protrusion portion may not overlap the gate electrode.

The first source active hole can include a first sub-active hole and a second sub-active hole spaced apart from each other, and the first drain active hole can include a first sub-active hole and a second sub-active hole spaced apart from each other.

The first sub-active hole and the second sub-active hole of the first source active hole can be in contact with each other, and the first sub-active hole and the second sub-active hole of the first drain active hole can be in contact with each other.

The active hole can further include a second active hole spaced apart from the first active hole, the second active hole may not overlap the gate electrode, and the second active hole can have a length in the second direction longer than a length in the first direction.

A straight line passing through the first active hole can pass through the second active hole among any straight lines parallel to the first direction.

The second active hole can include a second source active hole disposed from the gate electrode toward the source area along the first direction in a plane; and a second drain active hole disposed from the gate electrode toward the drain area along the first direction in a plane.

The thin film transistor can further comprise: a source electrode in contact with the source area through a contact hole; and a drain electrode spaced apart from the source electrode and in contact with the drain area through a contact hole.

Another configuration of the present invention provides a display apparatus including the thin film transistor.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a plan view of a thin film transistor according to an embodiment of the present invention.

FIG. 2 is a cross-sectional view taken along line I-I′ of FIG. 1 according to an embodiment of the present invention.

FIG. 3 is a cross-sectional view taken along line II-II′ of FIG. 1 according to an embodiment of the present invention.

FIG. 4 is a plan view of a thin film transistor according to another embodiment of the present invention.

FIG. 5 is a plan view of a thin film transistor according to another embodiment of the present invention.

FIG. 6 is a plan view of a thin film transistor according to another embodiment of the present invention.

FIG. 7 is a plan view of a thin film transistor according to another embodiment of the present invention.

FIG. 8 is a plan view of a thin film transistor according to another embodiment of the present invention.

FIG. 9 is a plan view of a thin film transistor according to another embodiment of the present invention.

FIG. 10 is a plan view of a thin film transistor according to another embodiment of the present invention.

FIG. 11 is a plan view of a thin film transistor according to another embodiment of the present invention.

FIG. 12 is a plan view of a thin film transistor according to another embodiment of the present invention.

FIG. 13 is a plan view of a thin film transistor according to another embodiment of the present invention.

FIG. 14 is a plan view of a thin film transistor according to another embodiment of the present invention.

FIG. 15 is a plan view of a thin film transistor according to another embodiment of the present invention.

FIG. 16A is a plan view of a thin film transistor according to another embodiment of the present invention.

FIG. 16B is a plan view of a thin film transistor according to a comparative example.

FIG. 17 is a graph measuring a threshold voltage Vth of a thin film transistor according to an embodiment of the present invention and a comparative example.

FIG. 18 is a schematic diagram of a display apparatus according to an embodiment of the present invention.

FIG. 19 is a schematic diagram of a shift register according to an embodiment of the present invention.

FIG. 20 is a circuit diagram of any one pixel of FIG. 18 according to an embodiment of the present invention.

FIG. 21 is a plan view of the pixel of FIG. 20 according to an embodiment of the present invention.

FIG. 22 is a cross-sectional view taken along line III-III′ of FIG. 21 according to an embodiment of the present invention.

FIG. 23 is a circuit diagram of any one pixel of a display apparatus according to another embodiment of the present invention.

FIG. 24 is a circuit diagram of any one pixel of a display apparatus according to an embodiment of the present invention.

### DETAILED DESCRIPTION OF THE DISCLOSURE

Advantages and features of the present disclosure and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a situation where “comprise,” “have” and “include” described in the present disclosure are used, another portion can be added unless “only˜” is used. The terms of a singular form can include plural forms unless referred to the contrary.

In construing an element, the element is construed as including an error band although there is no explicit description.

In describing a position relationship, e.g., when the position relationship is described as “upon,” “above,” “below” and “next to,” one or more portions can be disposed between two other portions unless “just” or “direct” is used.

Spatially relative terms such as “below,” “beneath,” “lower,” “above,” and “upper” can be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below,” or “beneath” another device can be arranged “above” another device. Therefore, an exemplary term “below or beneath” can include “below or beneath” and “above” orientations. Likewise, an exemplary term “above” or “on” can include “above” and “below or beneath” orientations.

In describing a temporal relationship, e.g., when the temporal order is described as “after,” “subsequent,” “next,” and “before,” a situation which is not continuous can be included, unless “just” or “direct” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” can include all combinations of two or more elements selected from the first, second and third elements as well as each element of the first, second and third elements.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode can be interchanged. The source electrode can be the drain electrode and vice versa. In addition, the source electrode of any one embodiment can be a drain electrode in another embodiment, and the drain electrode of any one embodiment can be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area can be the source electrode, and the drain area can be the drain electrode. In addition, the source area can be the drain electrode, and the drain area can be the source electrode.

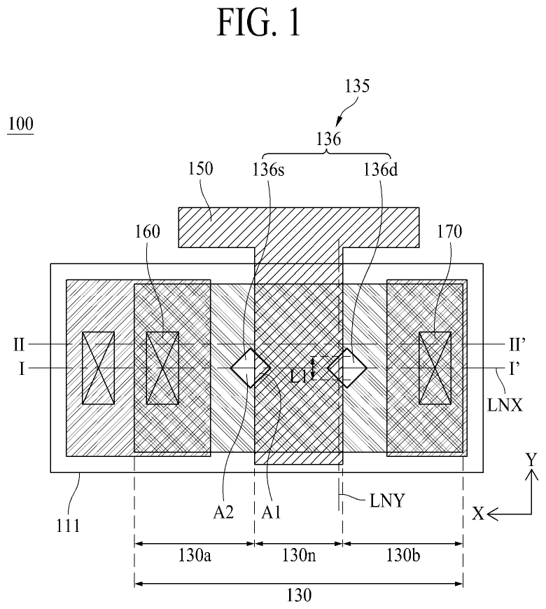

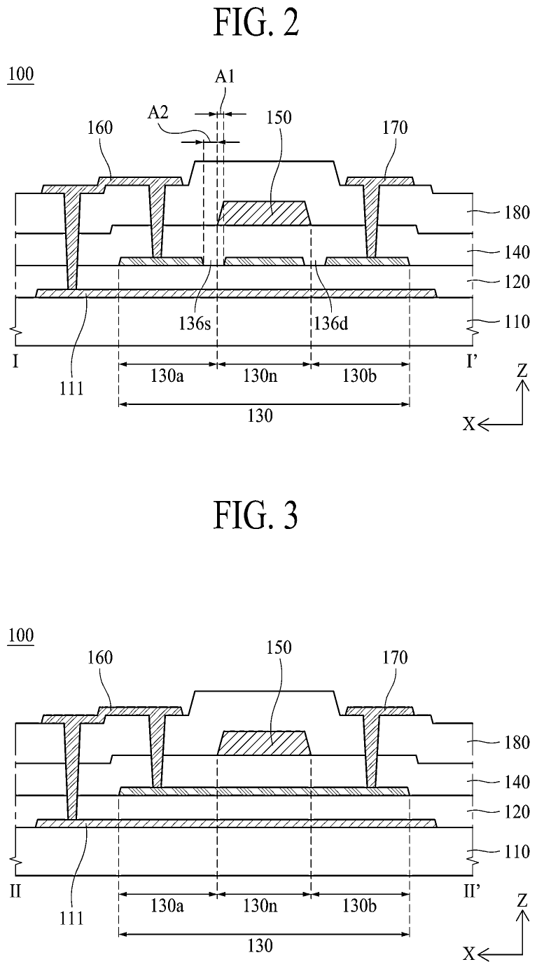

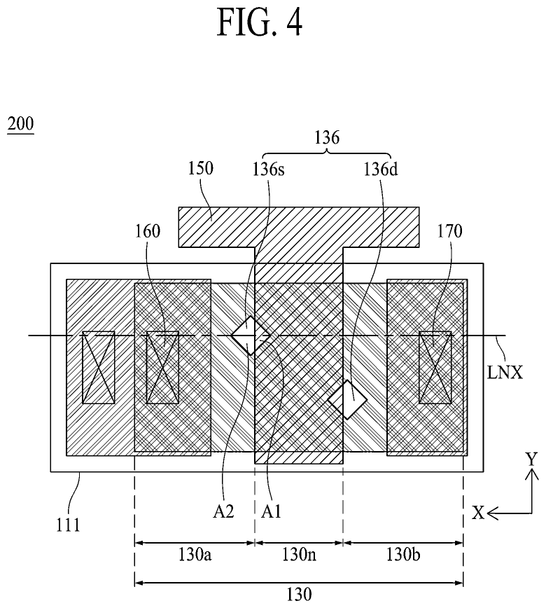

FIG. 1 is a plan view of a thin film transistor 100 according to an embodiment of the present invention. FIG. 2 is a cross-sectional view taken along line I-I′ of FIG. 1. FIG. 3 is a cross-sectional view taken along line II-II′ of FIG. 1 according to an embodiment of the present invention.

Specifically, referring to FIGS. 1, 2 and 3, an active layer 130 on the base substrate 110 and a gate electrode 150 spaced apart from the active layer 130 and partially overlapping with the active layer 130 can be included.

According to an embodiment of the present invention, the thin film transistor 100 can further include the base substrate 110. Referring to FIGS. 2 and 3, the active layer 130 is disposed on the base substrate 110.

According to an embodiment of the present invention, the thin film transistor 100 can further include a buffer layer 120. Referring to FIGS. 2 and 3, the active layer 130 is disposed on the buffer layer 120. Specifically, the buffer layer 120 is disposed between the base substrate 110 and the active layer 130.

According to an embodiment of the present invention, the thin film transistor 100 can further include a gate insulating layer 140. Referring to FIGS. 2 and 3, the gate insulating layer 140 is disposed on the active layer 130. Specifically, the gate insulating layer 140 is disposed between the active layer 130 and the gate electrode 150.

According to an embodiment of the present invention, the thin film transistor 100 can further include another layer disposed on the gate electrode 150. In detail, the thin film transistor 100 can further include an interlayer insulating layer 180. Referring to FIG. 3, the interlayer insulating layer 180 is disposed on the gate electrode 150. In detail, the gate electrode 150 is disposed between the gate insulating layer 140 and the interlayer insulating layer 180.

According to an embodiment of the present invention, the thin film transistor 100 can further include a source electrode 160 and a drain electrode 170. Referring to FIGS. 1, 2, and 3, the source electrode 160 and the drain electrode 170 are disposed on the gate insulation layer 140.

Hereinafter, components of the thin film transistor 100 according to an embodiment of the present invention will be described in more detail.

Glass or plastic can be used as the base substrate 110. A transparent plastic having flexible characteristics as plastic, e.g., polyimide, can be used.

When polyimide is used as the base substrate 110, considering that a high-temperature deposition process is performed on the base substrate 110, heat-resistant polyimide capable of withstanding high-temperature can be used. In this situation, in order to form a thin film transistor, processes such as deposition, etching, and the like can be performed in a state in which a polyimide substrate is disposed on a carrier substrate made of a highly durable material such as glass.

Referring to FIGS. 2 and 3, a buffer layer 120 can be disposed on the base substrate 110.

The buffer layer 120 can be formed on the base substrate 110 and can be formed of an inorganic material or an organic material. For example, insulating oxides such as silicon oxide (SiOx), aluminum oxide (Al₂O₃) and the like can be included.

The buffer layer 120 blocks impurities such as moisture and oxygen flowing from the base substrate 110 to protect the active layer 130, planarize the upper portion of the base substrate 110, and can be formed as a single layer or a plurality of layers.

Referring to FIGS. 2 and 3, the active layer 130 can be disposed on the buffer layer 120.

The active layer 130 can include a channel area 130n, a source area 130a, and a drain area 130b.

The channel area 130n overlaps with the gate electrode 150. The channel area 130n serves as a channel of the thin film transistor 100.

Specifically, the active layer 130 can include a channel area 130n partially overlapping with the gate electrode 150 in a plane or in a plan view, a source area 130a connected to one side of the channel area 130n without overlapping with the gate electrode 150 in a plane or in a plan view, and a drain area 130b connected to the other side of the channel area 130n without overlapping with the gate electrode 150 in a plane or in a plan view.

According to an embodiment of the present invention, the source area 130a and the drain area 130b are spaced apart from each other with the channel area 130n interposed therebetween.

According to a configuration of the present invention, the active layer 130 can be formed of a semiconductor material. The active layer 130 can include an oxide semiconductor material.

The oxide semiconductor material can include at least one of an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FelnZnO)-based oxide semiconductor material. However, an embodiment of the present invention is not limited thereto, and the active layer 130 can be made of another oxide semiconductor material known in the art.

The source area 130a and the drain area 130b can be formed by selective conductorization with respect to the active layer 130 made of a semiconductor material. According to an embodiment of the present invention, imparting conductivity to a specific portion of the active layer 130 so that this portion can function as a conductor is called selective conductorization. A portion to which conductivity is imparted by selective conductorization is converted into a conductor, and a portion to which conductivity is not imparted is not converted into a conductor.

The source area 130a and the drain area 130b shown in FIGS. 1, 2 and 3 are portions to which conductivity is imparted by selective conductorization.

According to an embodiment of the present invention, a selective conductorization can be formed by doping using a dopant. In addition, a selective conductorization can be formed by plasma treatment.

Selective conductorization of the active layer 130 can be performed by dopant doping using the gate electrode 150 or a photoresist as a mask. The dopant can include at least one of boron (B), phosphorus (P), fluorine (F), and hydrogen (H), for example.

When the active layer 130 is selectively conductorized by doping the dopant, the region of the active layer 130 doped with the dopant is selectively conductorized to become a source area 130a or a drain area 130b. The region of the active layer 130 that is not doped with the dopant may not be conductorized, and can become a channel area 130n.

Alternatively, the active layer 130 can be selectively conductorization by plasma treatment applied to a process of patterning the gate insulating layer 140. For example, plasma can be used in a process of patterning the gate insulating layer 140, and a portion of the active layer 130 contacting the plasma can be selectively conductorized to become a source area 130a or a drain area 130b of the active layer 130. A portion of the active layer 130 that is protected by the gate insulating layer 140 and is not in contact with the plasma can be a channel area 130n without being conductorized.

A configuration in which the active layer 130 is formed of one layer is disclosed in FIGS. 1, 2 and 3, but a configuration of the present invention is not limited thereto. The active layer 130 can have a single layer structure or a multilayer structure.

Referring to FIGS. 1, 2 and 3, the active hole 135 (e.g., one or more holes in the active layer) in which the active layer 130 is not disposed is disposed in the region in which the edge is defined by the active layer 130. According to an embodiment of the present invention, the active hole 135 is disposed in the region defined by the active layer 130 on a plane or in a plan view. Specifically, the active hole 135 can be formed by removing a portion of the active layer 130 by patterning.

Referring to FIGS. 1 and 2, the active hole 135 can be a region formed by removing a portion of the active layer 130. Since the active hole 135 can be referred to as a hole formed in the active layer 130 by removing a portion of the active layer 130, according to an embodiment of the present invention, the hole is referred to as an “active hole.”

According to an embodiment of the present invention, the active hole 135 can include a first active hole 136 partially overlapping with the gate electrode 150. Specifically, the active hole 135 includes a first active hole 136, and at least a portion of the first active hole 136 can overlap with the gate electrode 150.

FIGS. 1 and 2 show a configuration in which a part of the first active hole 136 overlaps with the gate electrode 150.

The gate insulating layer 140 is disposed on the active layer 130. The gate insulating layer 140 protects the channel area 130n.

The gate insulating layer 140 has insulating properties. The gate insulating layer 140 can include at least one of, e.g., silicon oxide, silicon nitride, and metallic oxide. The gate insulating layer 140 can have a single layer structure or a multilayer structure.

Referring to FIGS. 2 and 3, the gate insulating layer 140 is not patterned and can be disposed on the entire surface of the base substrate 110. However, an embodiment of the present invention is not limited thereto, and the gate insulating layer 140 can have a patterned structure.

The gate electrode 150 is disposed on the gate insulating layer 140. The gate electrode 150 overlaps the channel area 130n of the active layer 130.

The gate electrode 150 can include at least one among an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, and chromium (Cr), tantalum (Ta), neodium (Nd), and titanium (Ti). The gate electrode 150 can have a multilayer structure including at least two conductive layers each having different physical properties. For example, the gate electrode 150 can include at least one of molybdenum (Mo) and titanium (Ti).

According to an embodiment of the present invention, the gate insulating layer 140 can be patterned by etching using the gate electrode 150 as a mask, and in this process, the active layer 130 can be selectively conductorized to form a source area 130a and a drain area 130b. Specifically, according to an embodiment of the present invention, a region of the active layer 130 overlapping with the gate electrode 150 is not conductorized to form a channel area 130n having semiconductor characteristics, and a region not overlapping the gate electrode 150 can be conductorized to form a source area 130a and a drain area 130b.

Referring to FIGS. 2 and 3, an interlayer insulating layer 180 can be disposed on the gate electrode 150. The interlayer insulating layer 180 can be formed of an organic or inorganic insulating material. The interlayer insulating layer 180 can be formed of a composite layer of an organic layer and an inorganic layer.

According to an embodiment of the present invention, the thin film transistor 100 can include a source electrode 160 and a drain electrode 170 disposed on the interlayer insulating layer 180. Positions of the source electrode 160 and the drain electrode 170 can be reversed. However, an embodiment of the present invention is not limited thereto, and the source area 130a and the drain area 130b can serve as source and drain electrodes, respectively.

Referring to FIGS. 1, 2 and 3, the source electrode 160 and the drain electrode 170 can be connected to the active layer 130 through a contact hole, respectively. Specifically, the source electrode 160 can be in contact with the source area 130a through a contact hole. The drain electrode 170 can be spaced apart from the source electrode 160 and can be in contact with the drain area 130b through a contact hole.

Referring to FIGS. 1, 2 and 3, the light blocking layer 111 can be disposed on the base substrate 110. Specifically, the light blocking layer 111 can be disposed between the base substrate 110 and the active layer 130. The light blocking layer 111 overlaps with the channel area 130n. The light blocking layer 111 blocks light incident from the outside, thereby protecting the channel area 130n.

The light blocking layer 111 can be formed of a material having light blocking characteristics. The light blocking layer 111 can include at least one of an aluminum-based metal such as aluminum (Al) or an aluminum alloy, a molybdenum-based metal such as molybdenum (Mo) or a molybdenum alloy, chromium (Cr), tantalum (Ta), neodium (Nd), titanium (Ti), and iron (Fc). According to an embodiment of the present invention, the light blocking layer 111 can have electrical conductivity.

The light blocking layer 111 can be omitted. Also, a buffer layer can be additionally disposed between the base substrate 110 and the light blocking layer 111. The light blocking layer 111 can be electrically connected to one of the source electrode 160 and the drain electrode 170. FIG. 2 illustrates a configuration in which the light blocking layer 111 is electrically connected to the source electrode 160.

According to an embodiment of the present invention, a portion of the first active hole 136 may not overlap the gate electrode 150. FIG. 1 illustrates a configuration in which a portion of the active hole 136 overlaps with a portion of the gate electrode 150, and another portion of the first active hole 136 is disposed away from the gate electrode 150 (e.g., another part of the active hole 136 may not overlap with the gate electrode 150) toward the source area 130a or the drain area 130b in the first direction X in a plan view.

Specifically, according to an embodiment of the present invention, the first active hole 136 can include a first area A1 overlapping with the gate electrode 150 and a second area A2 not overlapping with the gate electrode 150. More specifically, the second area A2 can be disposed away from the gate electrode 150 (e.g., not overlapping) toward the source area 130a or the drain area 130b in the first direction X.

According to an embodiment of the present invention, if a direction parallel to the shortest line connecting the source area 130a and the drain area 130b is defined as the first direction X, the length of the channel area 130n in the first direction X can be defined as the length of the channel area, and if a direction perpendicular to the first direction X is defined as the second direction Y, the width of the channel area 130n in the second direction Y can be defined as the width of the channel area.

When the channel area 130n has a large width, when conductorization with respect to the source area 130a and the drain area 130b is performed, an interface between the channel area 130n and the conductorization portion is increased, and thus conductorization diffusion toward the channel area 130n can be greatly performed. When conductorization diffusion toward the channel area 130n is greatly performed, the threshold voltage Vth of the thin film transistor 100 can move in a negative (−) direction, and driving stability of the thin film transistor 100 can be deteriorated. For example, when the channel area 130n is wide, more dopants can concentrate at the center area at the edges of the gate electrode 150, and the dopants can penetrate deeper and possibly extend laterally to seep under the gate electrode 150. In other words, the diffusion of conductorization can extend farther and deeper, which may be undesirable in certain situations and could cause non-uniformities.

On the other hand, when the channel area (130n) has a small width, the interface between the channel area (130n) and the conductorization portion decreases, suppressing the diffusion of conductorization toward the channel area (130n), while excessive oxygen flows into the channel area (130n) and reliability deterioration occurs.

According to an embodiment of the present invention, as illustrated in FIG. 1, a first active hole 136 is formed in a boundary region between the channel area 130n and the source area 130a and a boundary region between the channel area 130n and the drain area 130b. For example, the first active hole 136 can include two holes in the active layer 130 that are disposed on opposite sides of the gate electrode 150. As a result, the boundary surface between the channel area 130n and the source area 130a and the boundary surface between the channel area 130n and the drain area 130b are reduced, and thus conductorization diffusion toward the channel area 130n can be suppressed. For example, the dopant seepage or absorption into the active layer 130 can be blocked or controlled by the holes in the active layer 130.

As a result, even if the channel area 130n has a large width, the movement of the threshold voltage (Vth) of the thin film transistor 100 in the negative (−) direction is suppressed, thereby improving the driving stability of the thin film transistor 100. In this way, when manufacturing many thin film transistors, their characteristics can be uniformly controlled, which can improve image quality, produce a more uniform display image and reduce defects.

According to an embodiment of the present invention, the first active hole 136 can include a first area A1 overlapping with the gate electrode 150 and a second area A2 not overlapping with the gate electrode 150. In this situation, the area of the second area A2 of the first active hole 136 can be greater than or equal to the area of the first area A1 of the first active hole 136. For example, a hole in the active layer 130 can have a square shape and a portion of that square hole that overlaps with the gate electrode 150 can have a triangle shape, but embodiments are not limited thereto. For example, holes in the active layer 130 for controlling conductorization diffusion can have various shapes, such as square, circular, oval, polygon, triangular, etc., which is discussed in more detail below regarding various embodiments.

Areas of the first area A1 and the second area A2 mean areas occupied by the first area A1 and the second area A2 when viewed in a plan view.

According to an embodiment of the present invention, as the area of the second area A2 not overlapping with the gate electrode 150 is increased, conductorization diffusion toward the channel area 130n can be suppressed when conductorization with respect to the source area 130a and the drain area 130b is performed. As a result, movement of the threshold voltage Vth of the thin film transistor 100 in the negative (−) direction is suppressed, and thus driving stability of the thin film transistor 100 can be improved. In other words, the part of the hole in active layer 130 that does not overlap with the gate electrode 150 can be larger than the part of the hole that does overlap with the gate electrode 150.

In addition, according to an embodiment of the present invention, as the area of the first area A1 overlapping with the gate electrode 150 is smaller, a decrease in the area of the channel area 130n is prevented, so that a sufficient area of the channel area 130n can be secured. In other words, the channel area 130n can be made as large as possible, while still optimally managing the amount of conductorization diffusion. As a result, conductorization diffusion can be controlled or prevented, and excellent mobility can be secured.

According to an embodiment of the present invention, when a direction parallel to a shortest line connecting the source area 130a and the drain area 130b is referred to as a first direction X and a direction perpendicular to the first direction X is referred to as a second direction Y, a length L1 of an area where an arbitrary straight line LNY parallel to the second direction Y overlaps with the first area A1 in a plane view can decrease as a distance from the second area A2 with respect to the first direction X increases.

More specifically, the length of a region where an arbitrary straight line LNY parallel to the second direction Y and the first area A1 overlap with each other in a plan view means that the length L1 of a line segment where an arbitrary straight line LNY parallel to the second direction Y and the first area A1 overlap with each other. More specifically, when the length of the first active hole 136 in the second direction Y is defined as the length of the first active hole 136, the length of the first area A1 of the first active hole 136 decreases toward the inside of the gate electrode 150.

In FIG. 1, a configuration in which the length L1 of a region where an arbitrary straight line LNY parallel to the second direction Y overlaps with the first area A1 is reduced toward the inside of the gate electrode 150 is illustrated. As a result, a reduction in the area of the channel area 130n can be prevented, and thus a sufficient area of the channel area 130n can be secured. As a result, the diffusion of conductorization can be controlled or prevented, and excellent mobility can be secured.

Also, in FIG. 1, a configuration in which the length L1 of a region where an arbitrary straight line LNY parallel to the second direction Y overlaps with the first area A1 is constantly decreased toward the inside of the gate electrode 150 is illustrated. However, an embodiment of the present invention is not limited thereto, and can be rapidly decreased or gradually decreased toward the inside of the gate electrode 150.

According to an embodiment of the present invention, the first active hole 136 can include a first source active hole 136s disposed on one side of the gate electrode 150 toward the source area 130a along the first direction X in a plane, and a first drain active hole 136d disposed on another side of the gate electrode 150 toward the drain area 130b along the first direction X in a plane. In other words, the first source active hole 136s and the first drain active hole 136d can overlap with opposite edges of the gate electrode 150.

FIG. 1 illustrates a configuration in which the first source active hole 136s and the first drain active hole 136d are disposed from the gate electrode 150 toward the source area 130a and the drain area 130b in the first direction X, respectively.

According to an embodiment of the present invention, the first source active hole 136s and the first drain active hole 136d are disposed to be spaced apart from each other.

FIG. 1 illustrates a configuration in which the first source active hole (136s) and the first drain active hole (136d) are spaced apart from each other with the gate electrode (150) interposed therebetween.

According to an embodiment of the present invention, a straight line LNX passing through at least a portion of the first source active hole 136s among any straight lines parallel to the first direction X can pass through the first drain active hole 136d.

In FIG. 1, a configuration in which the first source active hole 136s and the first drain active hole 136d are disposed on an arbitrary straight line parallel to the first direction X is illustrated. Specifically, in FIG. 1, a configuration in which the first source active hole 136s and the first drain active hole 136d overlap each other with respect to the first direction X is illustrated. However, an embodiment of the present invention is not limited thereto, and at least a portion of the first source active hole 136s can overlap with at least a portion of the first drain active hole 136d with respect to the first direction X.

According to an embodiment of the present invention, even when the first source active hole 136s and the first drain active hole 136d are disposed on an arbitrary straight line parallel to the first direction X, a reduction in the area of the channel area 130n can be prevented, and thus a sufficient area of the channel area 130n can be secured. As a result, conductorization diffusion can be controlled or prevented, and excellent mobility can be secured.

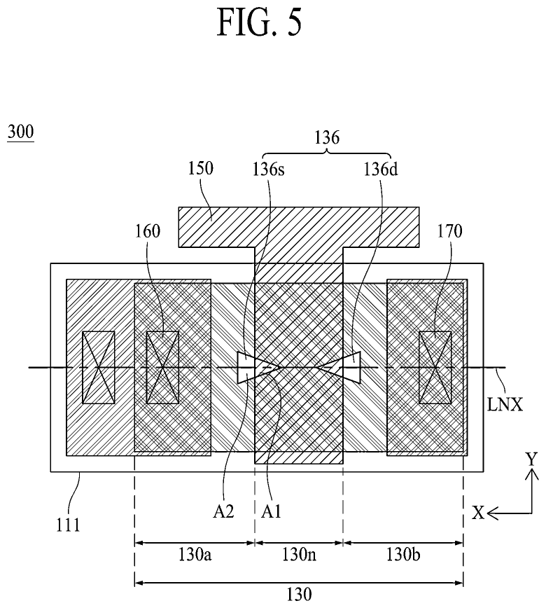

FIG. 4 is a plan view of a thin film transistor 200 according to another embodiment of the present invention.

According to an embodiment of the present invention, a straight line LNX passing through at least a portion of the first source active hole 136s among any straight lines parallel to the first direction X may not pass through the first drain active hole 136d.

FIG. 4 illustrates a configuration in which the first source active hole 136s and the first drain active hole 136d are not commonly disposed on an arbitrary straight line parallel to the first direction X. Specifically, FIG. 4 illustrates a configuration in which the first source active hole 136s and the first drain active hole 136d are spaced apart from each other with respect to the first direction X. For example, the first source active hole 136s and the first drain active hole 136d can be arranged “catty-cornered” with respect to each on opposite sides of the gate electrode 150.

According to an embodiment of the present invention, even when the first source active hole 136s and the first drain active hole 136d are not commonly disposed on an arbitrary straight line parallel to the first direction X, a reduction in the area of the channel area 130n can be prevented, and thus a sufficient area of the channel area 130n can be secured. As a result, conductorization diffusion can be controlled or prevented, and excellent mobility can be secured.

According to an embodiment of the present invention, the first active hole 136 can have a shape such as a semicircular shape, a fan shape, an arc shape, and a polygon shape. However, an embodiment of the present invention is not limited thereto, and the first active hole 136 can have various shapes.

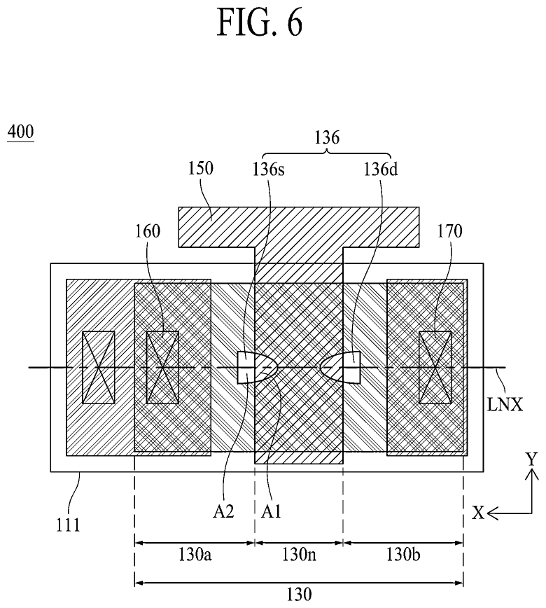

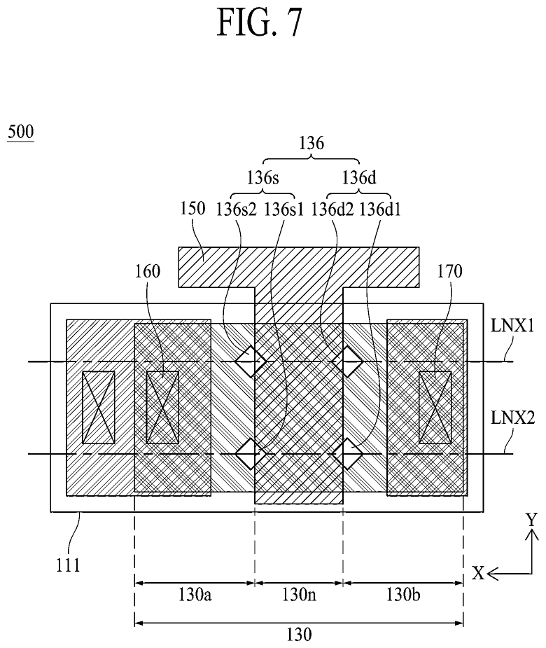

FIG. 5 is a plan view of a thin film transistor 300 according to another embodiment of the present invention. FIG. 6 is a plan view of a thin film transistor 400 according to another embodiment of the present invention.

Referring to FIG. 5, the first active hole 136 can have a shape of a triangle among polygons. Specifically, FIG. 5 shows a configuration in which each of the first source active hole 136s and the first drain active hole 136d has an isosceles triangle shape. Even in a situation in which the shapes of the first source active hole 136s and the first drain active hole 136d are triangular, when the second area A2 of the first source active hole 136s and the first drain active hole 136d are greater than or equal to the first area A1, a decrease in the channel area 130n can be prevented, and thus a sufficient area of the channel area 130n can be secured. As a result, conductorization diffusion can be controlled or prevented, and excellent mobility can be secured. For example, the first source active hole 136s and the first drain active hole 136d can have triangle shapes disposed on opposite sides of the gate electrode that point towards each other, but embodiments are not limited thereto.

Referring to FIG. 6, the first active hole 136 can have a bow shape among polygons. Specifically, FIG. 6 shows a configuration in which each of the first source active hole 136s and the first drain active hole 136d has a bow shape. For example, each of the first source active hole 136s and the first drain active hole 136d can have a semi-oval shape or a half-elliptical shape. Even in the situation in which the shapes of the first source active hole 136s and the first drain active hole 136d are bow shape, when the second area A2 of the first source active hole 136s and the first drain active hole 136d are greater than or equal to the first area A1, a reduction in the area of the channel area 130n is prevented, and thus a sufficient area of the channel area 130n can be secured. As a result, conductorization diffusion can be controlled or prevented, and excellent mobility can be secured.

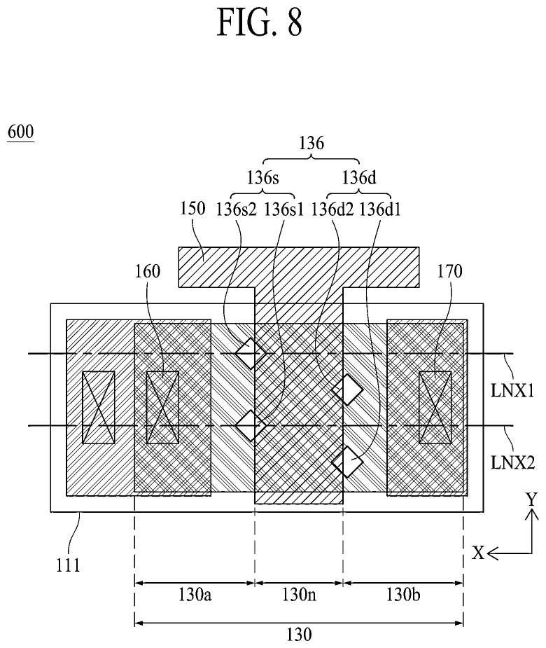

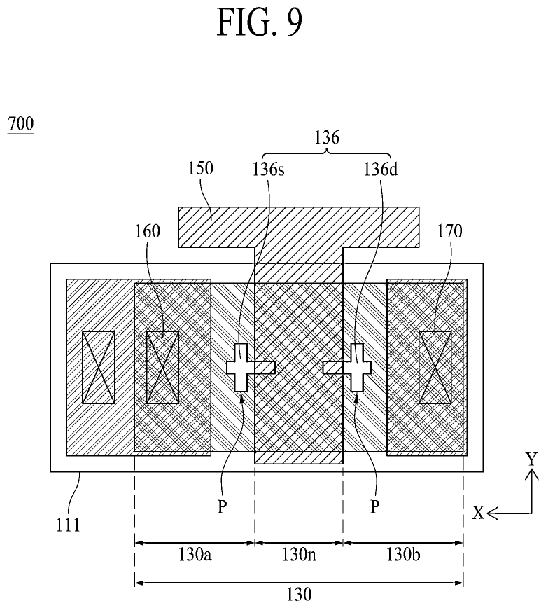

FIG. 7 is a plan view of a thin film transistor 500 according to another embodiment of the present invention. FIG. 8 is a plan view of a thin film transistor 600 according to another embodiment of the present invention.

According to an embodiment of the present invention, the first source active hole 136s can include a first sub-active hole 136s1 and a second sub-active hole 136s2 spaced apart from each other, and the first drain active hole 136d can include a first sub-active hole 136d1 and a second sub-active hole 136d2 spaced apart from each other. For example, a plurality of holes in the active layer 130 can be arranged on opposite sides of the gate electrode 150, in a grid pattern (e.g., 2×2, 3×2, 4×2, 4×4, etc.). Also, the plurality of holes in the active layer 130 can all be the same size, but embodiments are not limited thereto. For example, the plurality of holes in the active layer 130 can be different sizes or of mixed shapes and mixed sizes, according to embodiments.

Specifically, referring to FIG. 7, the first source active hole 136s and the first drain active hole 136d are spaced apart with the gate electrode 150 interposed therebetween, respectively, and the first sub-active hole 136s1 and the second sub-active hole 136s2 of the first source active hole 136s are disposed from the gate electrode 150 toward the source area 130a along the first direction X, and are disposed at a predetermined interval. Also, the first sub-active hole 136d1 and the second sub-active hole 136d2 of the first drain active hole 136d are disposed at a predetermined interval from the gate electrode 150 toward the drain area 130b.

In addition, the first sub-active hole 136s1 and the second sub-active hole 136s2 of the first source active hole 136s include a first area A1 overlapping with the gate electrode 150 and a second area A2 not overlapping with the gate electrode 150, respectively, and the second area A2 can be greater than or equal to the first area A1. The first sub-active hole 136d1 and the second sub-active hole 136d2 of the first drain active hole 136d also include the first area A1 overlapping with the gate electrode 150 and the second area A2 not overlapping with the gate electrode 150, and the second area A2 can be greater than or equal to the first area A1.

FIG. 7 and FIG. 8 illustrate only four holes in the active layer 130, but an embodiment of the present invention is not limited thereto, and the first source active hole 136s and the first drain active hole 136d can further include third sub-active holes 136s3 and 136d3 and fourth sub-active holes 136s4 and 136d4, respectively, and can further include five or more sub-active holes.

According to an embodiment of the present invention, a straight line LNX1 passing through the first sub-active hole 136s1 of the first source active hole 136s among any straight lines parallel to the first direction X can pass through the first sub-active hole 136d1 of the first drain active hole 136d, and a straight line LNX2 passing through the second sub-active hole 136s2 of the first source active hole 136s among any straight lines parallel to the first direction X can pass through the second sub-active hole 136d2 of the first drain active hole 136d.

FIG. 7 illustrates a configuration in which the first sub-active hole 136s1 of the first source active hole 136s and the first sub-active hole 136d1 of the first drain active hole 136d are disposed on an arbitrary straight line LNX1 parallel to the first direction X. Also, a configuration in which the second sub-active hole 136s2 of the first source active hole 136s and the second sub-active hole 136d2 of the first drain active hole 136d are disposed on an arbitrary straight line LNX2 parallel to the first direction X is illustrated.

However, an embodiment of the present invention is not limited thereto, and positions of the first sub-active hole 136s1 and the second sub-active hole 136s2 of the first source active hole 136s can be exchanged with each other or offset, and positions of the first sub-active hole 136d1 and the second sub-active hole 136d2 of the first drain active hole 136d can also be exchanged with each other or offset.

According to an embodiment of the present invention, a straight line passing through at least a portion of the first source active hole 136s among any straight lines parallel to the first direction X may not pass through the first drain active hole 136d.

Referring to FIG. 8, a straight line LNX1 passing through at least a portion of the first sub-active hole 136s1 of the first source active hole 136s among any straight lines parallel to the first direction X does not pass through any one of the first sub-active hole 136d1 and the second sub-active hole 136d2 of the first drain active hole 136d, and a straight line LNX2 passing through at least a portion of the second sub-active hole 136s2 of the first source active hole 136s among any straight lines parallel to the first direction X does not pass through any one of the first sub-active hole 136d1 and the second sub-active hole 136d2 of the first drain active hole 136d.

However, an embodiment of the present invention is not limited thereto, and positions of the first sub-active hole 136s1 and the second sub-active hole 136s2 of the first source active hole 136s can be exchanged with each other or offset, and positions of the first sub-active hole 136dl and the second sub-active hole 136d2 of the first drain active hole 136d can also be exchanged with each other or offset.

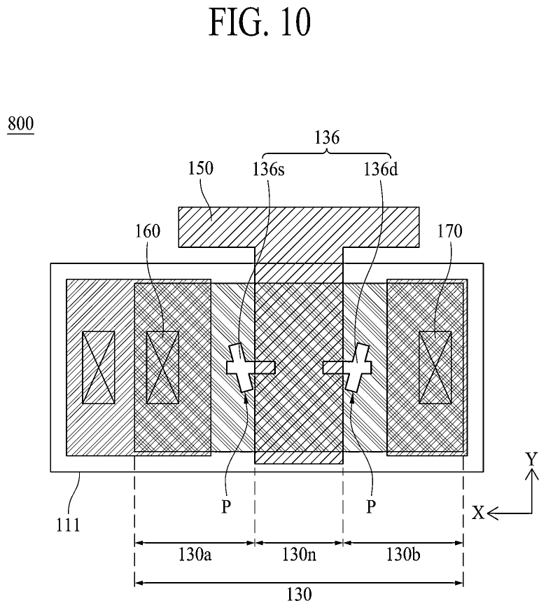

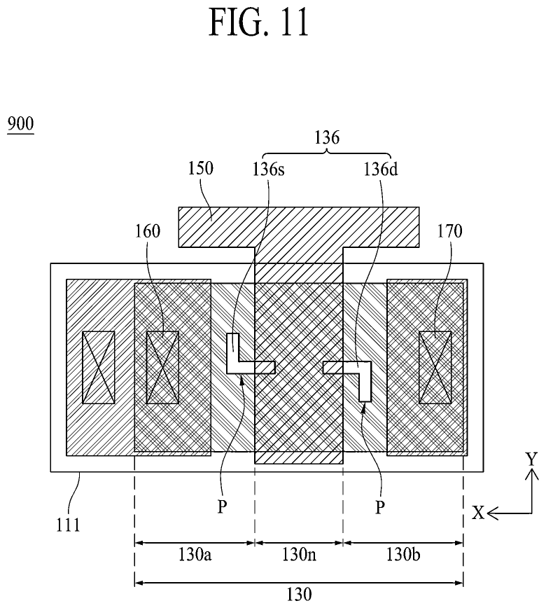

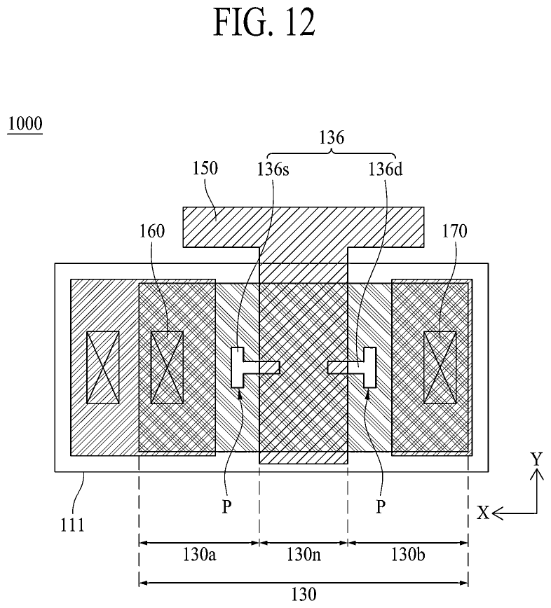

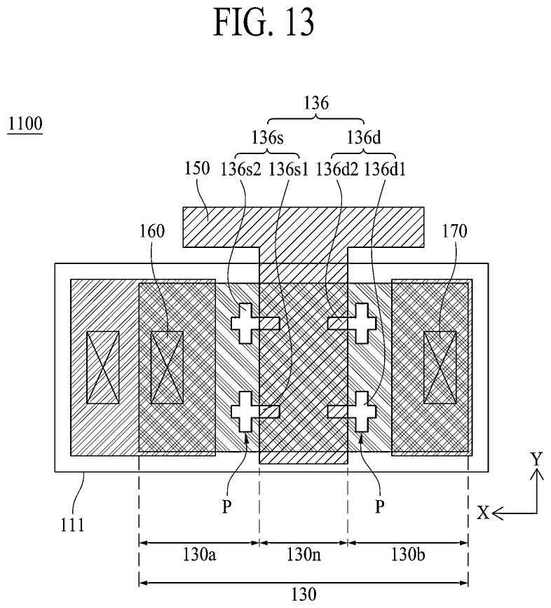

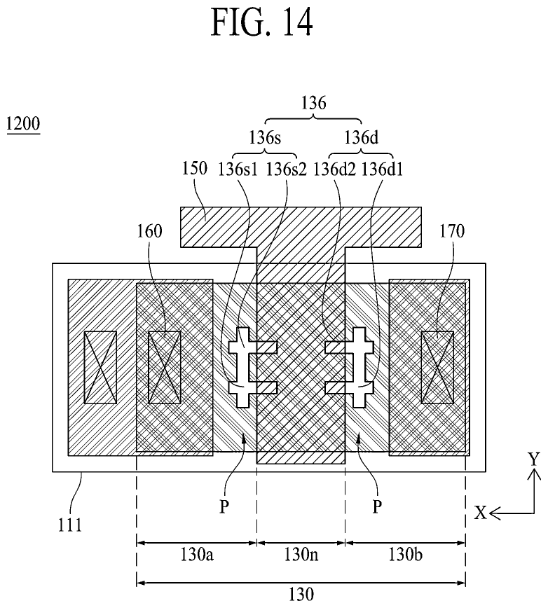

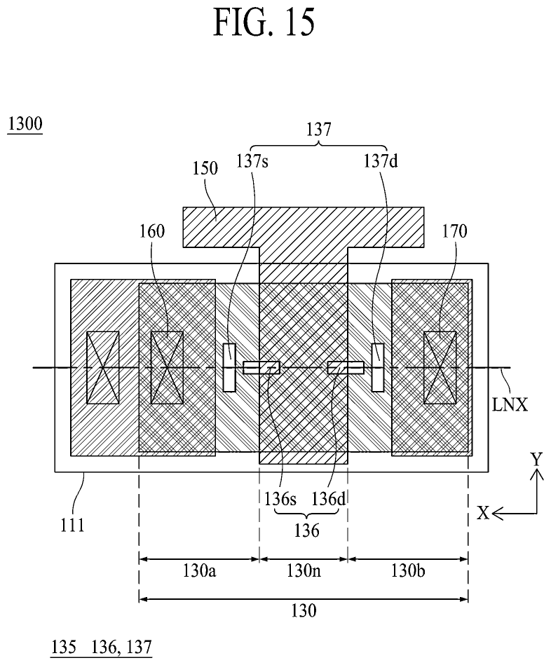

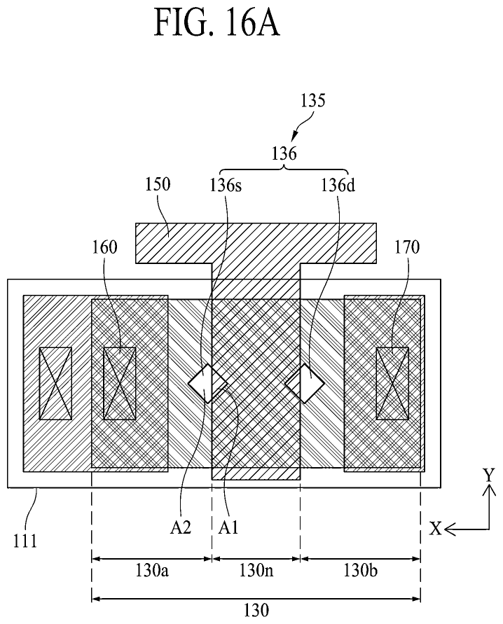

FIG. 9 is a plan view of a thin film transistor 700 according to another embodiment of the present invention. FIG. 10 is a plan view of a thin film transistor 800 according to another embodiment of the present invention. FIG. 11 is a plan view of a thin film transistor 900 according to another embodiment of the present invention. FIG. 12 is a view of a thin film transistor 1000 according to another embodiment of the present invention. FIG. 13 is a plan view of a thin film transistor 1100 according to another embodiment of the present invention. FIG. 14 is a plan view of a thin film transistor 1200 according to another embodiment of the present invention. FIG. 15 is a plan view of a thin film transistor 1300 according to another embodiment of the present invention.

According to an embodiment of the present invention, the first source active hole 136s and the first drain active hole 136d can further include a protrusion portion P disposed in a direction not parallel to the first direction X. For example, each of the first source active hole 136s and the first drain active hole 136d can have a “cross shape,” a “lowercase letter t” shape or a “plus sign” shape.

Since the first source active hole 136s and the first drain active hole 136d each further include the protrusion portion P disposed in a direction not parallel to the first direction X, when conductorization with respect to the source area 130a and the drain area 130b is performed, the conductorization diffusion path to the channel area 130n is blocked by the protrusion portion P, and thus conductorization diffusion toward the channel area 130n can be greatly suppressed. As a result, movement of the threshold voltage (Vth) of the thin film transistor 700 in the negative (−) direction is suppressed, and thus driving stability of the thin film transistor 700 can be improved.

FIG. 9 shows a configuration in which the first source active hole 136s and the first drain active hole 136d are spaced apart from each other and include protrusion portions P disposed in a direction not parallel to the first direction X. For example, each of the first source active hole 136s and the first drain active hole 136d can have a “cross shape,” a “lowercase letter t” shape or a “plus sign” shape, in which the cross member is diagonally disposed or non-perpendicular to the base portion.

According to an embodiment of the present invention, the protrusion portions P of the first source active hole 136s and the first drain active hole 136d may not overlap with the gate electrode 150. Also, even when the first source active hole 136s and the first drain active hole 136d each further include protrusion portions P, the second area A2 not overlapping with the gate electrode 150 is greater than or equal to the first area A1 overlapping the gate electrode 150, a reduction in the area of the channel area 130n can be prevented, and thus a sufficient area of the channel area 130n can be secured. As a result, conductorization diffusion can be controlled or prevented, and excellent mobility can be secured.

According to an embodiment of the present invention, the protrusion portions P of the first source active hole 136s and the first drain active hole 136d can be disposed in a direction parallel to the second direction Y.

In FIG. 9, a configuration in which protrusion portions P of the first source active hole 136s and the first drain active hole 136d are disposed in a direction parallel to the second direction Y is illustrated. Specifically, it can be disposed in a vertical direction to some regions of the first source active hole 136s and the first drain active hole 136d which are disposed in a direction parallel to the first direction X. However, an embodiment of the present invention is not limited thereto, and protrusion portions P of the first source active hole 136s and the first drain active hole 136d can be disposed in a direction not parallel to the second direction Y (see FIG. 10), the protrusion portions P can be disposed in only one of the second directions Y in the first source active hole 136s and the first drain active hole 136d (see FIG. 11), and protrusion portions P can be disposed in both directions in the second direction Y in the first source active hole 136s and the first drain active hole 136d (see FIG. 12). For example, each of the first source active hole 136s and the first drain active hole 136d can have a “capital T letter shape,” or an “L” shape. Also, each of the first source active hole 136s and the first drain active hole 136d can have point symmetry with respect to a center point between the first source active hole 136s and the first drain active hole 136d, but embodiments are not limited thereto. For example, each of the first source active hole 136s and the first drain active hole 136d can have mirror symmetry or be symmetrically arranged with respect to a center point between the first source active hole 136s and the first drain active hole 136d.

According to an embodiment of the present invention, the first source active hole 136s can include a first sub-active hole 136s1 and a second sub-active hole 136s2 spaced apart from each other, and the first drain active hole 136d can include a first sub-active hole 136d1 and a second sub-active hole 136d2 spaced apart from each other. For example, a plurality of “cross shaped” holes can be provided in the active layer 130 on opposite sides of the gate electrode 150 and the holes can be arranged in a grid (e.g., 2×2, 3×2, 4×2, 4×4, etc.), but embodiments are not limited thereto.

Specifically, referring to FIG. 13, the first source active hole 136s and the first drain active hole 136d are spaced apart from each other with the gate electrode 150 interposed therebetween, respectively, and the first sub-active hole 136s1 and the second sub-active hole 136s2 of the first source active hole 136s are disposed at a predetermined interval while protruding from the gate electrode 150 toward the source area 130a in the first direction X. Also, the first sub-active hole 136d1 and the second sub-active hole 136d2 of the first drain active hole 136d protrude from the gate electrode 150 toward the drain area 130b in the first direction X, and are disposed at a predetermined interval.

In FIG. 13, only the first sub-active holes 136s1 and 136d1 and the second sub-active holes 136s2 and 136d2 of the first source active hole 136s and the first drain active hole 136d are illustrated, but an embodiment of the present invention is not limited thereto, and the first source active hole 136s and the first drain active hole 136d can further include third sub-active holes 136s3 and 136d3 and fourth sub-active holes 136s4 and 136d4, respectively, and can further include five or more sub-active holes.

According to an embodiment of the present invention, the first sub-active hole 136s1 and the second sub-active hole 136s2 of the first source active hole 136s can be in contact with each other or in communication with each other, and the first sub-active hole 136d1 and the second sub-active hole 136d2 of the first drain active hole 136d can be in contact with each other or in communication with each other.

More specifically, referring to FIG. 14, a protrusion portion P of each of the first sub-active hole 136s1 and the second sub-active hole 136s2 can be in contact with each other (e.g., two connected cross shapes or connected “t” shapes). Also, a protrusion portion P of each of the first sub-active hole 136d1 and the second sub-active hole 136d2 of the first drain active hole 136d can be in contact with each other. More specifically, when the first source active hole 136s and the first drain active hole 136d include a plurality of sub-active holes, protrusion portions P of a plurality of sub-active holes can be connected to protrusion portions P of other adjacent sub-active holes. Even in this situation, when conductorization with respect to the source area 130a and the drain area 130b is performed, a conductorization diffusion path to the channel area 130n is blocked by the protrusion portion P, and thus conductorization diffusion toward the channel area 130n can be greatly suppressed. As a result, movement of the threshold voltage (Vth) of the thin film transistor 700 in the negative (−) direction is suppressed, and thus driving stability of the thin film transistor 700 can be improved.

According to an embodiment of the present invention, the active hole 135 can further include a second active hole 137 spaced apart from the first active hole 136. For example, the active layer 130 can include a plurality of holes on opposite sides of the gate electrode 150, and the holes can include a mix of different shapes, sizes and varying orientations.

Specifically, referring to FIG. 15, the active hole 135 can further include a second active hole 137 spaced apart from the first active hole 136 and not overlapping with the gate electrode 150, in addition to the first active hole 136 partially overlapping with the gate electrode 150.

According to an embodiment of the present invention, the second active hole 137 can have a length in the second direction Y longer than a length in the first direction X, and a straight line LNX passing through the first active hole 136 among any straight lines parallel to the first direction X can pass through the second active hole 137.

According to an embodiment of the present invention, the second active hole 137 can include a second source active hole 137s disposed from the gate electrode 150 toward the source area 130a along the first direction X in a plane or in a plan view, and a second drain active hole 137d disposed from the gate electrode 150 toward the drain area 130b along the first direction X in a plane or in a plan view.

Specifically, referring to FIG. 15, a configuration in which the first source active hole 136s and the first drain active hole 136d of the first active hole 136 are arranged in a straight line with an arbitrary straight line LNX parallel to the second source active hole 137s and the second drain active hole 137d of the second active hole 137 and the first direction X is illustrated. However, an embodiment of the present invention is not limited thereto, and the first source active hole 136s of the first active hole 136 and the second source active hole 137s of the second active hole 137 are arranged in a straight line with an arbitrary straight line LNX parallel to the first direction X, or the first drain active hole 136d of the first active hole 136 and the second drain active hole 137d of the second active hole 137 are arranged in a straight line with an arbitrary straight line LNX parallel to the first direction X, and the source active holes 136s and 137s and the drain active hole 136d and 137d are not necessarily arranged in a straight line with an arbitrary straight line LNX parallel to the first direction X.

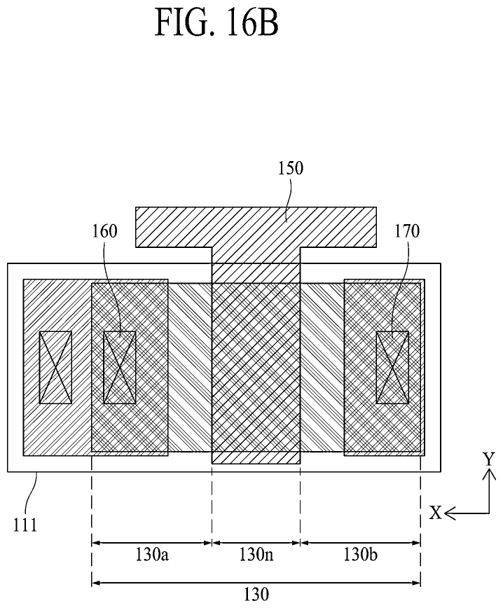

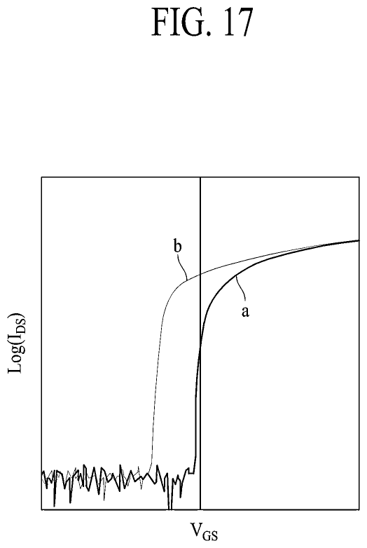

FIG. 16A is a plan view of a thin film transistor according to an embodiment of the present invention. FIG. 16B is a plan view of a thin film transistor according to a comparative example in which the active layer 130 does not include any active holes. FIG. 17 is a graph measuring a threshold voltage Vth of a thin film transistor according to the example embodiment and the comparative example.

Referring to FIG. 17, graph “a” shows a threshold voltage Vth measurement result of the thin film transistor according to an embodiment of FIG. 16A, and graph “b” shows a threshold voltage Vth measurement result of the thin film transistor according to a comparative example of FIG. 16B.

In the graph of FIG. 17, the horizontal axis represents a gate voltage Vas, and the vertical axis represents a log value of the drain-source current IDS.

Referring to FIG. 16A, the thin film transistor according to an embodiment can include a first active hole 136, and the thin film transistor according to an embodiment can be any one of the thin film transistors 100, 200, 300, 400, 500, 600, 800, 900, 1000, 1100, 1200 and 1300 of FIGS. 1 through 15. In contrast, referring to FIG. 16B, the thin film transistor according to the comparative example does not include the active hole 135.

Referring to FIG. 17, in the situation corresponding to graph “a” of an embodiment including a first active hole 136, when conductorization is performed with respect to the source area 130a and the drain area 130b, diffusion of conductorization toward the channel area 130n can be suppressed. As a result, movement of the threshold voltage (Vth) of the thin film transistor 100 in the negative (−) direction can be suppressed, and thus, driving stability of the thin film transistor 100 can be improved. Also, reduction of the area of the channel area 130n can be prevented, so that a sufficient area of the channel area 130n can be secured. As a result, diffusion of conductorization can be controlled or prevented, and excellent mobility can be secured.

On the other hand, in the situation corresponding to graph “b” of the comparative example that does not include the first active hole 136, conductorization of the source area 130a and the drain area 130b can proceed and seep under the gate electrode, and thus conductorization diffusion toward the channel area 130n can be greatly performed, which reduces the size of the channel area. As a result, it can be confirmed that the threshold voltage Vth of the thin film transistor moves in the negative (−) direction, which can impair the driving stability.

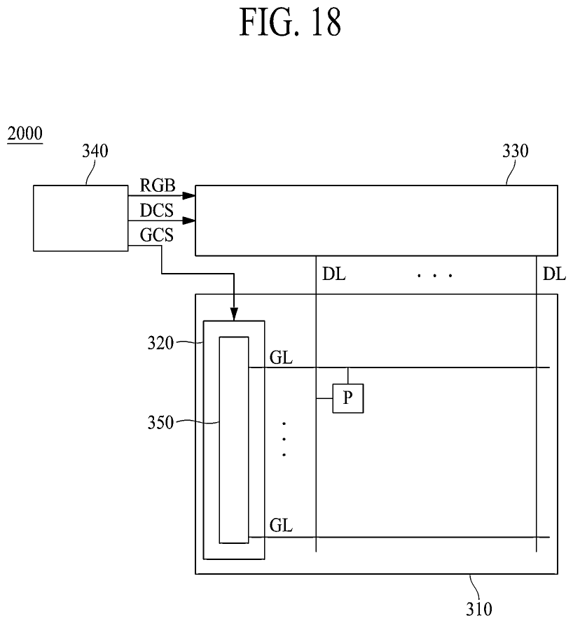

FIG. 18 is a schematic diagram illustrating a display apparatus 2000 according to further still another embodiment of the present disclosure.

As shown in FIG. 18, the display apparatus 2000 according to further still another embodiment of the present disclosure can include a display panel 310, a gate driver 320, a data driver 330 and a controller 340.

The display panel 310 includes gate lines GL and data lines DL, and pixels P are disposed in intersection areas of the gate lines GL and the data lines DL. An image is displayed by driving of the pixels P. The gate lines GL, the data lines DL and the pixels P can be disposed on the base substrate 110.

The controller 340 controls the gate driver 320 and the data driver 330.

The controller 340 outputs a gate control signal GCS for controlling the gate driver 320 and a data control signal DCS for controlling the data driver 330 by using a signal supplied from an external system. Also, the controller 340 samples input image data input from the external system, realigns the sampled data and supplies the realigned digital image data RGB to the data driver 330.

The gate control signal GCS includes a gate start pulse GSP, a gate shift clock GSC, a gate output enable signal GOE, a start signal Vst and a gate clock GCLK. Also, control signals for controlling a shift register can be included in the gate control signal GCS.

The data control signal DCS includes a source start pulse SSP, a source shift clock signal SSC, a source output enable signal SOE and a polarity control signal POL.

The data driver 330 supplies a data voltage to the data lines DL of the display panel 310. In detail, the data driver 330 converts the image data RGB input from the controller 340 into an analog data voltage and supplies the data voltage to the data lines DL.

According to one embodiment of the present disclosure, the gate driver 320 can be packaged on the display panel 310. In this way, a structure in which the gate driver 320 is directly packaged on the display panel 310 will be referred to as a Gate In Panel (GIP) structure. In detail, in the Gate In Panel (GIP) structure, the gate driver 320 can be disposed on the base substrate 110.

The display apparatus 2000 according to one embodiment of the present disclosure can include the above-described thin film transistors 100, 200, 300, 400, 500, 600, 700, 800, 900, 1000, 1100, 1200, and 1300. According to one embodiment of the present disclosure, the gate driver 320 can include the above-described thin film transistors 100, 200, 300, 400, 500, 600, 700, 800, 900, 1000, 1100, 1200, and 1300.

The gate driver 320 can include a shift register 350.

The shift register 350 sequentially supplies gate pulses to the gate lines GL for one frame by using the start signal and the gate clock, which are transmitted from the controller 340. In this situation, one frame means a time period at which one image is output through the display panel 310. The gate pulse has a turn-on voltage capable of turning on a switching device (thin film transistor) disposed in the pixel P.

Also, the shift register 350 supplies a gate-off signal capable of turning off the switching device, to the gate line GL for the other period of one frame, at which the gate pulse is not supplied. Hereinafter, the gate pulse and the gate-off signal will be collectively referred to as a scan signal SS or Scan.

The shift register 350 can include the above-described thin film transistors 100, 200, 300, 400, 500, 600, 700, 800, 900, 1000, 1100, 1200, and 1300.

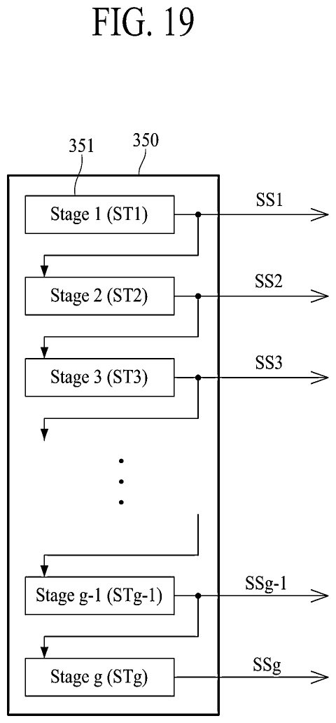

FIG. 19 is a schematic diagram illustrating a shift register 350.

Referring to FIG. 19, the shift register 350 can include g number of stages 351 (STI to STg).

The shift register 350 transmits one scan signal SS to pixels P connected to one gate line GL through one gate line GL. Each of the stages 351 can be connected to one gate line GL. When g number of gate lines GL are formed in the display panel 110, the shift register 350 can include g number of stages 351 (STI to STg), and can generate g number of scan signals SS1 to SSg.

In general, each stage 351 outputs the gate pulse GP once during one frame, and the gate pulses GP are sequentially output from each stage 351.

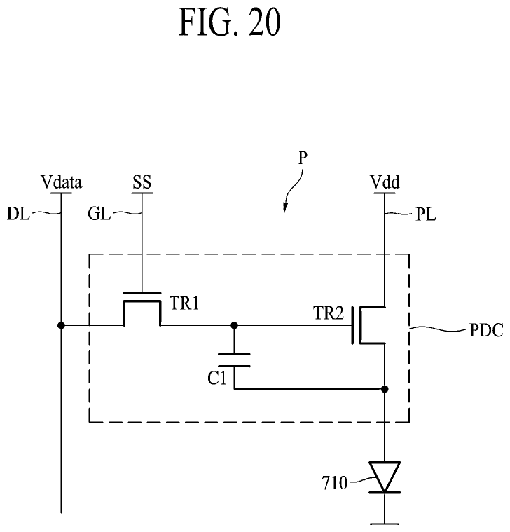

FIG. 20 is a circuit view illustrating any one pixel P of FIG. 18.

The circuit view of FIG. 20 is an equivalent circuit view for the pixel P of the display apparatus 2000 that includes an organic light emitting diode (OLED) as a display element 710.

Referring to FIG. 20, the pixel P includes a display element 710 and a pixel driving circuit PDC for driving the display element 710. In detail, the display apparatus 2000 according to one embodiment of the present disclosure can include a pixel driving circuit PDC on the base substrate 110.

The pixel driving circuit PDC of FIG. 20 includes a first thin film transistor TR1 that is a switching transistor and a second thin film transistor TR2 that is a driving transistor. The display apparatus 2000 according to another embodiment of the present disclosure can include at least one of the above-described thin film transistors 100, 200, 300, 400, 500, 600, 700, 800, 900, 1000, 1100, 1200, and 1300.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls applying of the data voltage Vdata.

The driving power line PL provides a driving voltage Vdd to the display element 710, and the first thin film transistor TR1 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 320 through the gate line GL, the data voltage Vdata supplied through the data line DL is supplied to a gate electrode of the second thin film transistor TR2 connected to the display element 710. The data voltage Vdata is charged in a storage capacitor C1 formed between the gate electrode and a source electrode of the second thin film transistor TR2.

The amount of a current supplied to the organic light emitting diode (OLED), which is the display element 710, through the second thin film transistor TR2 is controlled in accordance with the data voltage Vdata, whereby a gray scale of light output from the display element 710 can be controlled.

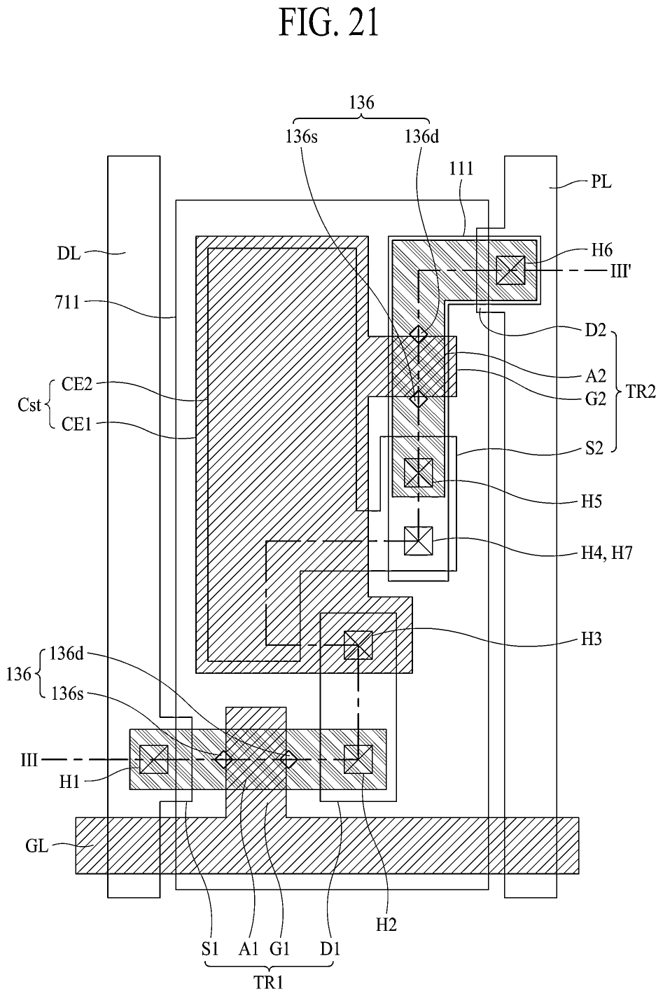

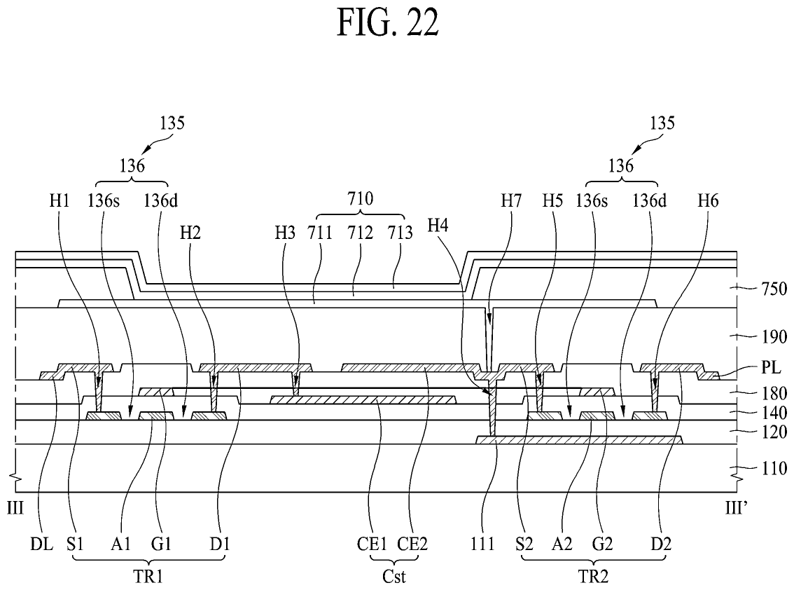

FIG. 21 is a plan view of the pixel of FIG. 20 according to an embodiment of the present disclosure, and FIG. 22 is a cross-sectional view taken along line III-III′ of FIG. 21 according to an embodiment of the present disclosure.

Referring to FIGS. 21 and 22, the first thin film transistor TR1 and the second thin film transistor TR2 are disposed on the base substrate 110.

The base substrate 110 can be made of glass or plastic. As the base substrate 110, plastic having flexible characteristics, e.g., polyimide (PI), can be used.

The light blocking layer 111 is disposed on the base substrate 110. The light blocking layer 111 can have a light blocking characteristic. The light blocking layer 111 can block light incident from the outside to protect the active layers A1 and A2 from damage or degradation.

The buffer layer 120 is disposed on the light blocking layer 111. The buffer layer 120 is made of an insulating material and protects the active layers A1 and A2 from moisture or oxygen introduced from the outside.

A first active layer A1 of the first thin film transistor TR1 and a second active layer A2 of the second thin film transistor TR2 are disposed on the buffer layer 120.

The first active layer A1 and the second active layer A2 can include, e.g., an oxide semiconductor material. The first active layer A1 and the second active layer A2 can be formed of an oxide semiconductor layer made of an oxide semiconductor material.

In the first thin film transistor TR1, the first active layer A1 can include a channel area, a source area, and a drain area. A channel area of the first active layer A1 overlaps the gate electrode G1. According to another embodiment of the present invention, a source area can be referred to as a source electrode S1, and a drain area can be referred to as a drain electrode D1.

In the second thin film transistor TR1, the second active layer A2 can include a channel area, a source area, and a drain area. The channel area of the second active layer A2 overlaps the gate electrode G2. According to another embodiment of the present invention, a source area can be referred to as a source electrode S2, and a drain area can be referred to as a drain electrode D2.

In the first thin film transistor TR1, an active hole 135 in which the first active layer A1 is not disposed is disposed in an area in which an edge thereof is defined by the first active layer A1. The active hole 135 can be an area formed by removing the active layers A1 and A2.

The active hole 135 includes a first active hole 136, and at least a portion of the first active hole 136 can overlap with the gate electrodes G1 and G2. Specifically, the first active hole 136 includes a first source active hole 136s and a first drain active hole 136d disposed from the gate electrodes G1 and G2, and at least a portion of each of the first source active hole 136s and the first drain active hole 136d can overlap with the gate electrodes G1 and G2.

The gate insulating layer 140 is disposed on the active layers A1 and A2. The gate insulating layer 140 covers upper surfaces of the active layers A1 and A2.

The gate electrode G1 of the first thin film transistor TR1 and the gate electrode G2 of the second thin film transistor TR2 are disposed on the gate insulating layer 140.

In addition, a gate line GL can be disposed on the gate insulating layer 140. The gate electrode G1 of the first thin film transistor TR1 can extend from the gate line GL or can be a part of the gate line GL.

Referring to FIGS. 21 and 22, a first capacitor electrode CE1 of the storage capacitor Cst is formed on the gate insulating layer 140. The first capacitor electrode CE1 can be formed by the same material as the gate electrodes G1 and G2 by the same process.

An interlayer insulating layer 180 is disposed on the gate electrodes G1 and G2 and the first capacitor electrode CE1.

A data line DL and a driving power line PL are disposed on the interlayer insulating layer 180. Also, the source electrode S1 and the drain electrode D1 of the first thin film transistor TR1 are disposed on the interlayer insulating layer 180, and the source electrode S2 and the drain electrode D2 of the second thin film transistor TR2 are disposed on the interlayer insulating layer 180.

The source electrode S1 of the first thin film transistor TR1 can be integrally formed with the data line DL, and can have a structure extending from the data line DL.

The source electrode S1 of the first thin film transistor TR1 can be in contact with the side surface of the active layer A1 of the first thin film transistor TR1 through the first contact hole H1.

A drain electrode D1 of the first thin film transistor TR1 contacts another side surface of the active layer A1 of the first thin film transistor TR1 through a second contact hole H2. Also, a drain electrode D1 of the first thin film transistor TR1 is connected to the first capacitor electrode CE1 through a third contact hole H3. As a result, the first capacitor electrode CE1 can be connected to the first thin film transistor TR1.

The drain electrode D2 of the second thin film transistor TR2 can be integrally formed with the driving power line PL, and can have a structure extending from the driving power line PL.

The drain electrode D2 of the second thin film transistor TR2 can be in contact with the side surface of the active layer A2 of the second thin film transistor TR2 through the sixth contact hole H6.

The source electrode S2 of the second thin film transistor TR2 is in contact with the other side surface of the active layer A2 of the second thin film transistor TR2 through the fifth contact hole H5. Also, the source electrode S2 of the second thin film transistor TR2 is connected to the light blocking layer 111 through the fourth contact hole H4. The same voltage as the source electrode S2 of the second thin film transistor TR2 can be applied to the light blocking layer 111 overlapping with the second thin film transistor TR2.

The source electrode S2 of the second thin film transistor TR2 can extend onto the interlayer insulating layer 180 to form the second capacitor electrode CE2 of the storage capacitor Cst.

According to an embodiment of the present invention, the first capacitor electrode CE1 and the second capacitor electrode CE2 can overlap with each other to form a storage capacitor Cst.

Referring to FIGS. 21 and 22, a planarization layer 190 is disposed on the data line DL, the driving power line PL, the source electrodes S1 and S2, the drain electrodes D1 and D2, and the second capacitor electrode CE2. The planarization layer 190 planarizes upper portions of the first thin film transistor TR1 and the second thin film transistor TR2, and protects the first thin film transistor TR1 and the second thin film transistor TR2. The planarization layer 190 serves as a protective layer.

A first electrode 711 of the display element 710 is disposed on the planarization layer 190. The first electrode 711 of the display element 710 is in contact with the second capacitor electrode CE2 through a seventh contact hole H7 formed in the planarization layer 180. As a result, the first electrode 711 of the display element 710 can be connected to the source electrode S2 of the second thin film transistor TR2.

A bank layer 750 is disposed at an edge of the first electrode 711. The bank layer 750 defines a light emitting area of the display element 710.

The organic light emitting layer 712 is disposed on the first electrode 711, and the second electrode 713 is disposed on the organic light emitting layer 712. Accordingly, the display element 710 is completed. The display element 710 shown in FIG. 20 is an organic light emitting diode (OLED). Therefore, the display apparatus 2000 according to an embodiment of the present invention is an organic light emitting display apparatus.

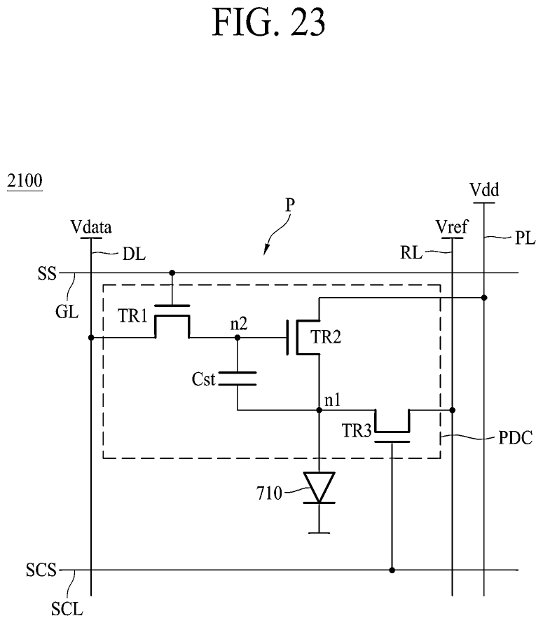

FIG. 23 is a circuit diagram of any one pixel of a display apparatus 2100 according to another embodiment of the present invention.

FIG. 23 is an equivalent circuit diagram of a pixel P of an organic light emitting display apparatus.

The pixel P of the display apparatus 2100 shown in FIG. 23 includes an organic light emitting diode OLED, which is a display element 710, and a pixel driving circuit PDC for driving the display element 710. The display element 710 is connected to the pixel driving circuit PDC.

Signal lines DL, GL, PL, RL, and SCL for supplying signals to the pixel driving circuit PDC are arranged in the pixel P.

The data voltage Vdata is supplied to the data line DL, the scan signal SS is supplied to the gate line GL, the driving voltage Vdd for driving the pixel is supplied to the driving power line PL, the reference voltage Vref is supplied to the reference line RL, and the sensing control signal SCS is supplied to the sensing control line SCL.

The pixel driving circuit PDC includes, e.g., the first thin film transistor TR1 (switching transistor) connected to the gate line GL and the data line DL, the second thin film transistor TR2 (driving transistor) that controls the magnitude of the current output to the display element 710 according to the data voltage Vdata transmitted through the first thin film transistor TR1, and the third thin film transistor TR3 (sensing transistor) for sensing the characteristics of the second thin film transistor TR2.

The first thin film transistor TR1 is turned on by the scan signal SS supplied to the gate line GL, and transmits the data voltage Vdata supplied to the data line DL to the gate electrode of the second thin film transistor TR2.

The third thin film transistor TR3 is connected to the first node n1 and the reference line RL between the second thin film transistor TR2 and the display element 710, is turned on or off by the sensing control signal SCS, and detects characteristics of the second thin film transistor TR2, which is a driving transistor during the sensing period.

A second node n2 connected to the gate electrode of the second thin film transistor TR2 is connected to the first thin film transistor TR1. A storage capacitor Cst is formed between the second node n2 and the first node n1.

When the first thin film transistor TR1 is turned on, the data voltage Vdata supplied through the data line DL is supplied to the gate electrode of the second thin film transistor TR2. The data voltage Vdata is charged in the storage capacitor Cst formed between the gate electrode and the source electrode of the second thin film transistor TR2.

When the second thin film transistor TR2 is turned on, current is supplied to the display element 710 through the second thin film transistor TR2 by the driving voltage Vdd driving the pixel, and light is output from the display element 710.

The display apparatus 2100 according to another embodiment of the present invention can include at least one of the thin film transistors 100, 200, 300, 400, 500, 600, 700, 800, 900, 1000, 1100, 1200, and 1300.

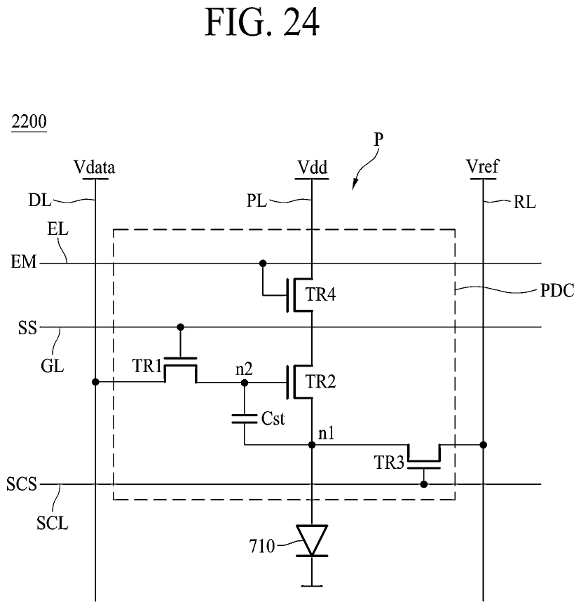

FIG. 24 is a circuit diagram of any one pixel P of a display apparatus 2200 according to another embodiment of the present invention.

The pixel P of the display apparatus 2200 shown in FIG. 24 includes an organic light emitting diode OLED, which is a display element 710, and a pixel driving circuit PDC for driving the display element 710. The display element 710 is connected to the pixel driving circuit PDC.

The pixel driving circuit PDC includes thin film transistors TR1, TR2, TR3, and TR4.

Signal lines DL, EL, GL, PL, SCL, and RL that supply driving signals to the pixel driving circuit PDC are arranged in the pixel P.

Compared with the pixel P of FIG. 23, the pixel P of FIG. 24 further includes an emission control line EL. The emission control signal EM is supplied to the emission control line EL. Also, compared with the pixel driving circuit PDC of FIG. 23, the pixel driving circuit PDC of FIG. 24 further includes a fourth thin film transistor TR4, which is an emission control transistor for controlling an emission time point of the second thin film transistor TR2.

The first thin film transistor TR1 is turned on by the scan signal SS supplied to the gate line GL, and transmits the data voltage Vdata supplied to the data line DL to the gate electrode of the second thin film transistor TR2.

A storage capacitor Cst is positioned between the gate electrode of the second thin film transistor TR2 and the display element 710.

The third thin film transistor TR3 is connected to the reference line RL, is turned on or off by the sensing control signal SCS, and detects characteristics of the third thin film transistor TR3, which is a driving transistor, during the sensing period.

The fourth thin film transistor TR4 transfers the driving voltage Vdd to the second thin film transistor TR2 or blocks the driving voltage Vdd according to the emission control signal EM. When the fourth thin film transistor TR4 is turned on, a current is supplied to the second thin film transistor TR2 to output light from the display element 710.

The pixel driving circuit PDC according to another exemplary configuration of the present invention can be formed in various structures other than the structure described above. The pixel driving circuit PDC can include, e.g., five or more thin film transistors.

According to the present disclosure, the following advantageous effects can be obtained.

The thin film transistor according to an embodiment of the present invention, including an active hole, diffusion of conductorization can be controlled or prevented even if the width of the channel area increases.

The thin film transistor according to an embodiment of the present invention can control or prevent diffusion of conductorization by controlling the active hole, and ensure excellent mobility.

The thin film transistor according to a configuration of the present invention can have excellent reliability, including an active hole.

In addition to the above-mentioned effects, other features and advantages of the present invention will be described below or clearly understood by those of ordinary skill in the art to which the present invention belongs from such technology and description.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A thin film transistor comprising:
an active layer; and
a gate electrode spaced apart from the active layer, the gate electrode at least partially overlapping with the active layer,
wherein the active layer includes:
a channel area at least partially overlapping with the gate electrode in a plan view;
a source area connected to one side of the channel area;
a drain area connected to another side of the channel area; and
an active hole penetrating through opposite sides of the active layer, the active hole including a first active hole,
wherein at least a portion of the first active hole overlaps with the gate electrode,
wherein the first active hole includes:
a first area overlapping with the gate electrode; and
a second area that does not overlap with the gate electrode, and
wherein an area of the second area is greater than or equal to an area of the first area.

2. The thin film transistor of claim 1, wherein a direction parallel to a shortest line connecting the source area and the drain area is a first direction, and a direction perpendicular to the first direction is a second direction, and
wherein a width of the first active hole in the second direction decreases as a distance away from the second area in the first direction increases.

3. The thin film transistor of claim 1, wherein a direction parallel to a shortest line connecting the source area and the drain area is a first direction, and a direction perpendicular to the first direction is a second direction,
wherein the first active hole includes:
a first source active hole extending away from the gate electrode toward the source area along the first direction; and
a first drain active hole extending away from the gate electrode toward the drain area along the first direction, and
wherein the first source active hole and the first drain active hole are spaced apart from each other.

4. The thin film transistor of claim 3, wherein a straight line parallel to the first direction passes through at least a portion of the first source active hole and also passes through at least a portion of the first drain active hole.

5. The thin film transistor of claim 3, wherein a straight line parallel to the first direction passes through at least a portion of the first source active hole and does not pass through the first drain active hole.

6. The thin film transistor of claim 3, wherein the first source active hole includes a first sub-active hole and a second sub-active hole spaced apart from each other, and
wherein the first drain active hole includes a first sub-active hole and a second sub-active hole spaced apart from each other.

7. The thin film transistor of claim 6, wherein a straight line parallel to the first direction passes through the first sub-active hole of the first source active hole and passes through the first sub-active hole of the first drain active hole, and
wherein a straight line parallel to the first direction passes through the second sub-active hole of the first source active hole and passes through the second sub-active hole of the first drain active hole.

8. The thin film transistor of claim 6, wherein a straight line parallel to the first direction passes through at least a portion of the first source active hole and does not pass through the first drain active hole.

9. The thin film transistor of claim 3, wherein each of the first source active hole and the first drain active hole further include a protrusion portion that is disposed in a direction that is not parallel to the first direction.

10. The thin film transistor of claim 9, wherein the protrusion portion does not overlap with the gate electrode.

11. The thin film transistor of claim 9, wherein the first source active hole includes a first sub-active hole and a second sub-active hole spaced apart from each other, and
wherein the first drain active hole includes a first sub-active hole and a second sub-active hole spaced apart from each other.

12. The thin film transistor of claim 11, wherein the first sub-active hole and the second sub-active hole of the first source active hole are in contact with each other or in communication with each other, and
wherein the first sub-active hole and the second sub-active hole of the first drain active hole are in contact with each other or in communication with each other.

13. The thin film transistor of claim 3, wherein the active hole further includes a second active hole spaced apart from the first active hole,
wherein the second active hole does not overlap the gate electrode, and
wherein the second active hole has a length in the second direction that is longer than a length of the second active hole in the first direction.

14. The thin film transistor of claim 13, wherein a straight line parallel to the first direction passes through the first active hole and passes through the second active hole.

15. The thin film transistor of claim 13, wherein the second active hole includes:
a second source active hole extending away from the gate electrode toward the source area along the first direction; and
a second drain active hole extending away from the gate electrode toward the drain area along the first direction.

16. The thin film transistor of claim 1, further comprising:
a source electrode in contact with the source area through a contact hole; and
a drain electrode spaced apart from the source electrode and in contact with the drain area through a contact hole.

17. A display apparatus comprising the thin film transistor of claim 1.

18. A thin film transistor comprising:
an active layer disposed on a substrate;
a gate electrode overlapping with the active layer;
a source electrode electrically connected to the active layer;
a drain electrode electrically connected to the active layer; and
at least one hole in the active layer,
wherein the at least one hole at least partially overlaps with an edge of the gate electrode,
wherein the at least one hole includes two holes penetrating through the active layer,
wherein the two holes overlap with opposite edges of the gate electrode, and
wherein the two holes have tapered shapes that point towards each other.

19. The thin film transistor of claim 18, wherein the two holes have mirror symmetry.

20. The thin film transistor of claim 18, wherein the at least one hole includes a plurality of holes having different sizes or different shapes, and
wherein each of the plurality of holes at least partially overlaps with the gate electrode.
